(19) United States
(12) Patent Application Publication
(10) Pub. No.: US 2006/0140036 A1
(43) Pub. Date: Jun. 29, 2006

(54) Memory controller, display controller, and memory control method

(75) Inventor: Toshiyuki Yamamoto, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/314,645

(22) Filed: Dec. 21, 2005

(30) Foreign Application Priority Data
Dec. 28, 2004 (JP) 2004-380984

(51) Int. Cl. G11C 7/00

(52) U.S. Cl. 365/222

(57) ABSTRACT

A memory controller includes: a splitter which divides input pixel data, in which the number of bits of a first color component is I1 bits, the number of bits of a second color component is I2 bits, and the number of bits of a third color component is I3 bits, into a basic data portion and an extension data portion, the number of bits of the first color component being J1 bits, the number of bits of the second color component being J2 bits, and the number of bits of the third color component being J3 bits (J1+J2+J3=2^{M}) in the basic data portion, and the number of bits of the first color component being K1 bits, the number of bits of the second color component being K2 bits, and the number of bits of the third color component being K3 bits (K1+K2+K3=2^{N}) in the extension data portion; and an address generator which generates access addresses for writing the basic data portion into a basic data storage region of the memory and writing the extension data portion into an extension data storage region of the memory.

Japanese Patent Application No. 2004-380984, filed on Dec. 28, 2004, is hereby incorporated by reference in its entirety.

### BACKGROUND OF THE INVENTION

The present invention relates to a memory controller, a display controller, and a memory control method.

A computer generally uses data or an address of which the number of bits is a power of two, such as 8 bits or 16 bits. On the other hand, a display device such as a liquid crystal display (LCD) generally uses pixel data of which the number of bits is not a power of two.

FIG. 1A shows an example of an RGB666 format (18 bits per pixel (bpp)). In the RGB666 format, the number of bits of each of R, G, and B components of one pixel is six bits so that 262,144-color representation is enabled.

The pixel data in the RGB666 format is 18-bit data, and is not data of which the number of bits is a power of two. It is desirable that the pixel data be data of which the number of bits is a power of two, such as 16 bits (e.g. RGB565 format), so that a computer can easily process the data. However, since only 65,536 colors can be represented when the pixel data is 16 bits, high-definition image representation cannot be realized. Therefore, the RGB666 format as shown in FIG. 1A is used when high-definition image representation is important.

As the technology of storing pixel data in such an RGB format that the number of bits is not a power of two in a memory, the following related-art technologies can be given.

In a first related-art technology, as shown in FIG. 1B, pixel data is divided into color component units, and the data of each color component is stored in a memory having a word length of 32 bits from the byte (eight bits) boundary, for example. However, the first related-art technology requires a 3-byte region for storing the pixel data in the RGB666 format (18 bpp) as shown in FIG. 1A. Specifically, a 6-bit region is wasted in pixel units, so that the memory utilization efficiency is decreased.

In a second related-art technology (JP-A-2003-223134), as shown in FIG. 2, pixel data is stored from the head irrespective of the boundary and the color components of pixel data. In the second related-art technology, since the number of bits necessary for storing the entire pixel data is “number of bits per pixel×number of pixels”, the memory utilization efficiency is increased in comparison with the first related-art technology shown in FIG. 1B. However, addressing for accessing a specific pixel or color component becomes significantly complicated, as is clear from FIG. 2.

In a third related-art technology, as shown in FIG. 3A, pixel data is stored in a special memory having a word length which is an integral multiple of the number of bits of the pixel data. In FIG. 3A, since the number of bits of the pixel data is 18 bits, the pixel data is stored in a memory having a word length of 36 bits. The third related-art technology does not cause an unnecessary region to occur and facilitates addressing. However, a special memory having a word length of 36 bits is necessary. Therefore, a problem occurs in which the manufacture becomes difficult or a commercially available memory (memory having a word length of which the number of bits is a power of two) cannot be used.

Moreover, the third related-art technology has a problem in which it is difficult to deal with the number of RGB formats (bit modes). Specifically, since the third related-art technology uses a special memory having a word length of 36 bits, while addressing can be simplified for the RGB666 (18 bpp) format as shown in FIG. 3A, addressing becomes complicated for the RGB565 (16 bpp) format as shown in FIG. 3B.

### SUMMARY

A first aspect of the invention relates to a memory controller which controls access to a memory which stores pixel data, the memory controller comprising:

a splitter which divides input pixel data, in which the number of bits of a first color component is I1 bits, the number of bits of a second color component is I2 bits, and the number of bits of a third color component is I3 bits, into a basic data portion and an extension data portion, the number of bits of the first color component being J1 bits, the number of bits of the second color component being J2 bits, and the number of bits of the third color component being J3 bits (J1+J2+J3=2^{M}) in the basic data portion, and the number of bits of the first color component being K1 bits, the number of bits of the second color component being K2 bits, and the number of bits of the third color component being K3 bits (K1+K2+K3=2^{N}) in the extension data portion; and

an address generator which generates access addresses for writing the basic data portion into a basic data storage region of the memory and writing the extension data portion into an extension data storage region of the memory.

A second aspect of the invention relates to a display controller, comprising:

the above memory controller; and

a display device interface which performs interface processing between the display controller and a display device.

A third aspect of the invention relates to a display controller, comprising:

the above memory controller; and

at least one memory in which the basic data storage region and the extension data storage region are allocated.

A fourth aspect of the invention relates to a method of controlling a memory which stores pixel data, the method comprising:

dividing input pixel data, in which the number of bits of a first color component is I1 bits, the number of bits of a second color component is I2 bits, and the number of bits of a third color component is I3 bits, into a basic data portion and an extension data portion, the number of bits of the first color component being J1 bits, the number of bits of the second color component being J2 bits, and the number of bits of the third color component being J3 bits (J1+J2+J3=2^{M}) in the basic data portion, and the number of bits of the first color component being K1 bits, the number of bits of the second color component being K2 bits, and the number of bits of the third color component being K3 bits (K1+K2+K3=2^{N}) in the extension data portion; and

writing the basic data portion into a basic data storage region of the memory and writing the extension data portion into an extension data storage region of the memory.

### BRIEF DESCRIPTION OF THE SEVERAL VIEWS OF THE DRAWING

FIGS. 1A and 1B are illustrative of a first related-art technology.

FIG. 2 is illustrative of a second related-art technology.

FIGS. 3A and 3B are illustrative of a third related-art technology.

FIG. 4 is a configuration example of a memory controller and a display controller according to one embodiment of the invention.

FIGS. 5A and 5B are signal waveform examples in a host I/F.

FIG. 6 is a signal waveform example in the host I/F.

FIGS. 7A and 7B are format examples of data signals of a display device I/F.

FIG. 8 is illustrative of a division and combination method according to one embodiment of the invention.

FIG. 9 shows a storage state of a basic data portion and an extension data portion.

FIG. 10 is illustrative of a division and combination method according to one embodiment of the invention.

FIG. 11 shows a storage state of a basic data portion and an extension data portion.

FIG. 12 is illustrative of a division and combination method according to one embodiment of the invention.

FIG. 13 shows a storage state of a basic data portion and an extension data portion.

FIG. 14 is a detailed configuration example of the memory controller and the display controller according to one embodiment of the invention.

FIG. 15 is illustrative of a method of realizing a subtractive color mode.

FIGS. 16A and 16B are illustrative of a method of realizing a complementary color mode.

### DETAILED DESCRIPTION OF THE EMBODIMENT

The invention may provide a memory controller, a display controller, and a memory control method capable of increasing the memory utilization efficiency and simplifying memory addressing.

One embodiment of the invention provides a memory controller which controls access to a memory which stores pixel data, the memory controller comprising:

a splitter which divides input pixel data, in which the number of bits of a first color component is I1 bits, the number of bits of a second color component is I2 bits, and the number of bits of a third color component is I3 bits, into a basic data portion and an extension data portion, the number of bits of the first color component being J1 bits, the number of bits of the second color component being J2 bits, and the number of bits of the third color component being J3 bits (J1+J2+J3=2^{M}) in the basic data portion, and the number of bits of the first color component being K1 bits, the number of bits of the second color component being K2 bits, and the number of bits of the third color component being K3 bits (K1+K2+K3=2^{N}) in the extension data portion; and

an address generator which generates access addresses for writing the basic data portion into a basic data storage region of the memory and writing the extension data portion into an extension data storage region of the memory.

According to one embodiment of the invention, the input pixel data is divided into the basic data portion, in which the first, second, and third color components are respectively J1 bits, J2 bits, and J3 bits, and the extension data portion, in which the first, second, and third color components are respectively K1 bits, K2 bits, and K3 bits. The basic data portion is written into the basic data storage region of the memory, and the extension data portion is written into the extension data storage region of the memory. According to one embodiment of the invention, the basic data portion satisfies the relationship “J1+J2+J3=2^{M}”, and the extension data portion satisfies the relationship “K1+K2+K3=2^{N}”. Therefore, the utilization efficiency of the memory in which the basic data portion and the extension data portion are allocated can be increased. Moreover, addressing can be simplified when requesting access to the memory.

With this embodiment,

the first color component, the second color component, and the third color component may be respectively an R component, a G component, and a B component; and

when pixel data in an RGB666 format, in which I1=I2=I3=6, is input, the splitter may divide the pixel data in the RGB666 format into a basic data portion in an RGB565 format, in which J1=5, J2=6, and J3=5, and an extension data portion in which K1=1, K2=0, and K3=1.

Therefore, even when pixel data in the RGB666 format of which the total number of bits is not a power of two is input, the pixel data can be efficiently stored in the memory. Moreover, since the basic data portion is in the RGB565 format, the basic data portion may be used for other applications such as the subtractive color mode.

With this embodiment,

the first color component, the second color component, and the third color component may be respectively an R component, a G component, and a B component; and

when pixel data in an RGB888 format, in which I1=I2=I3=8, is input, the splitter may divide the pixel data in the RGB888 format into a basic data portion in an RGB565 format, in which J1=5, J2=6, and J3=5, and an extension data portion in which K1=3, K2=2, and K3=3.

Therefore, even when pixel data in the RGB888 format of which the total number of bits is not a power of two is input, the pixel data can be efficiently stored in the memory. Moreover, since the basic data portion is in the RGB565 format, the basic data portion may be used for other applications such as the subtractive color mode.

With this embodiment, when pixel data in an RGB565 format, in which I1=5, I2=6, and I3=5, is input, the input pixel data in the RGB565 format may be written into the basic data storage region.

Therefore, when pixel data in the RGB565 format is input, the pixel data can be efficiently stored in the memory. Moreover, it becomes possible to deal with input of pixel data in different formats, such as the RGB666 format and the RGB565 format, the RGB888 format and the RGB566 format, or the RGB666 format, the RGB888 format, and the RGB566 format.

This embodiment may include a multiplexer which selects pixel data output from one of access request blocks requesting access to the memory, and outputs the selected pixel data to the splitter.

This enables addressing to be simplified when write requests are issued from the access request blocks, for example.

This embodiment may include: a combiner which combines the basic data portion stored in the basic data storage region and the extension data portion stored in the extension data storage region, and outputs pixel data in which the number of bits of the first color component is I1 bits, the number of bits of the second color component is I2 bits, and the number of bits of the third color component is I3 bits.

This enables the basic data portion stored in the basic data storage region and the extension data portion stored in the extension data storage region to be automatically combined.

This embodiment may include a demultiplexer which outputs the pixel data output from the combiner to one of access request blocks which request access to the memory.

This enables addressing to be simplified when read requests are issued from the access request blocks, for example.

With this embodiment, in a subtractive color mode, the basic data portion stored in the basic data storage region may be read and output as pixel data in the subtractive color mode.

This enables the subtractive color mode to be realized by using a simple configuration and simple processing.

With this embodiment, in a complementary color mode, the basic data portion stored in the basic data storage region may be read in order to generate pixel data in the complementary color mode including the basic data portion and a complementary color data portion.

This enables the complementary color mode to be realized by using a simple configuration and simple processing.

With this embodiment, the complementary color data portion may be generated based on the read basic data portion.

This simplifies the processing of generating the complementary color data portion.

With this embodiment, in the complementary color mode, the generated complementary color data portion may be written into the extension data storage region.

This makes it possible to store and retain the generated complementary color data portion.

Another embodiment of the invention provides a display controller comprising:

any of the above memory controllers; and

a display device interface which performs interface processing between the display controller and a display device.

This embodiment may include a host interface connected with a host processor through a 2^{R}-bit bus and performing interface processing between the display controller and the host processor.

A further embodiment of the invention provides a display controller comprising:

any of the above memory controllers; and

at least one memory in which the basic data storage region and the extension data storage region are allocated.

The basic data storage region and the extension data storage region may be allocated in different memories, such as allocating the basic data storage region in a first memory and allocating the extension data storage region in a second memory, or the basic data storage region and the extension data storage region may be allocated in an identical (single) memory.

A still further embodiment of the invention provides a method of controlling a memory which stores pixel data, the method comprising:

dividing input pixel data, in which the number of bits of a first color component is I1 bits, the number of bits of a second color component is I2 bits, and the number of bits of a third color component is I3 bits, into a basic data portion and an extension data portion, the number of bits of the first color component being J1 bits, the number of bits of the second color component being J2 bits, and the number of bits of the third color component being J3 bits (J1+J2+J3=2^{M}) in the basic data portion, and the number of bits of the first color component being K1 bits, the number of bits of the second color component being K2 bits, and the number of bits of the third color component being K3 bits (K1+K2+K3=2^{N}) in the extension data portion; and

writing the basic data portion into a basic data storage region of the memory and writing the extension data portion into an extension data storage region of the memory.

Note that the embodiments described hereunder do not in any way limit the scope of the invention defined by the claims laid out herein. Note also that not all of the elements of these embodiments should be taken as essential requirements to the means of the present invention.

Configuration

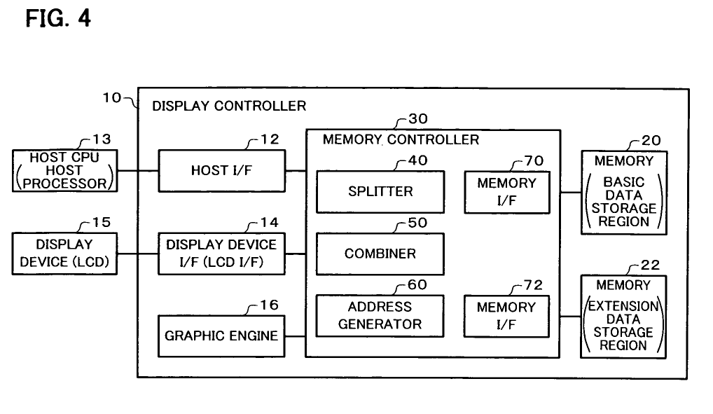

FIG. 4 shows a configuration example of a memory controller according to one embodiment of the invention and a display controller including the memory controller. The configurations of the memory controller and the display controller are not limited to the configurations shown in FIG. 4. Some of the constituent elements shown in FIG. 4 may be omitted, or another constituent element may be additionally provided.

A display controller 10 includes a host interface (I/F) 12. In the specification and the drawings, the term “interface” may be appropriately abbreviated as “I/F”. The host I/F 12 performs interface processing between the display controller 10 and a host CPU 13 (host processor in a broad sense). In more detail, the host I/F 12 performs processing of transmitting or receiving a command, data (pixel data), or status to or from the host CPU 13. The host I/F 12 and the host CPU 13 are connected through an 8-bit or 16-bit (2^{R}-bit in a broad sense) bus (data bus, address bus, or data/address bus), for example. The host CPU 13 controls the entire electronic instrument (e.g. portable telephone or portable information instrument) provided with the display controller 10, performs MPEG decode-encode processing, or performs baseband engine processing. The display controller 10 may include a circuit which performs MPEG decode-encode processing.

The display controller 10 includes a display device I/F 14 (LCD I/F). The display device I/F 14 performs interface processing between the display controller 10 and a display device 15 (display driver or display panel). In more detail, the display device I/F 14 performs processing of transmitting pixel data (image data, video data, or still image data) to the display device 15, processing of generating various control signals for the display device 15, or the like.

The display controller 10 includes a graphic engine 16 (image processing circuit). The graphic engine 16 performs image processing such as image rotation (mirror) processing, scaling (expansion-reduction) processing, or filter processing (gamma correction). In more detail, pixel data (image data) input from the host CPU 13 or pixel data obtained by a capturing operation of a camera (not shown) is written into memories 20 and 22. The graphic engine 16 performs image processing such as rotation processing or scaling processing for the pixel data stored in the memories 20 and 22. The pixel data after image processing is written into the memories 20 and 22, transferred to the host CPU 13 through the host I/F 12, or transferred to the display device 15 through the display device I/F 14.

The display controller 10 includes a memory controller 30. The memory controller 30 controls access (read or write access) to the memories 20 and 22. Specifically, the memory controller 30 arbitrates between accesses from access request blocks (peripheral circuits) such as the host I/F 12, the display device I/F 14, and the graphic engine 16. The memory controller 30 generates a read address or a write address of the memories 20 and 22, and reads or writes data (pixel data) from or into the memories 20 and 22.

The display controller 10 includes the memories 20 and 22 (VRAMs). The memories 20 and 22 store pixel data (image data, RGB data, or YUV data) or the like. The memories 20 and 22 are memories having a word length of 2^{P} bits (e.g. 32 bits, 64 bits, or 128 bits), and may be configured by using a DRAM, an SRAM, or the like.

The memories 20 and 22 may be built-in memories provided in the display controller 10 as shown in FIG. 4, or may be external memories provided outside the display controller 10. The memories 20 and 22 may be physically different memories, or may be a physically identical memory. Specifically, a basic data storage region may be allocated in the memory 20, and an extension data storage region may be allocated in the memory 22 physically different from the memory 20. Or, the basic data storage region and the extension data storage region may be allocated in an identical (single) memory. Information (e.g. program or table) other than pixel data may be stored in the memories 20 and 22.

The memory controller 30 includes a splitter 40. The splitter 40 (dividing circuit) performs processing of dividing pixel data into a basic data portion (data portion of basic bits) and an extension data portion (data portion of extension bits). Suppose that pixel data (image data), in which the number of bits of an R component (first color component in a broad sense) is I1 bits, the number of bits of a G component (second color component in a broad sense) is I2 bits, and the number of bits of a B component (third color component in a broad sense) is I3 bits, is input (e.g. I1+I2+I3=2^{M}+2^{N}; I1, I2, I3, M, and N are integers). In this case, the splitter 40 divides the input pixel data into a basic data portion, in which the number of bits of the R (red) component is J1 bits, the number of bits of the G (green) component is J2 bits, and the number of bits of the B (blue) component is J3 bits (J1+J2+J3=2^{M}), and an extension data portion, in which the number of bits of the R component is K1 bits, the number of bits of the G component is K2 bits, and the number of bits of the B component is K3 bits (K1+K2+K3=2^{N}) (J1, J2, J3, K1, K2, and K3 are integers). The memory controller 30 writes the basic data portion obtained by division into the basic data storage region (memory 20), and writes the extension data portion into the extension data storage region (memory 22). It should be understood that the case of dividing pixel data into three or more portions instead of dividing pixel data into two portions is also included within the scope of the invention.

The memory controller 30 includes a combiner 50. The combiner 50 (combining circuit) performs processing of combining the basic data portion and the extension data portion of the pixel data. In more detail, the combiner 50 combines the basic data portion stored in the basic data storage region of the memory 20 and the extension data portion stored in the extension data storage region of the memory 22. The combiner 50 then outputs the pixel data in which the number of bits of the R component is I1 bits, the number of bits of the G component is I2 bits, and the number of bits of the B component is I3 bits.

The memory controller 30 includes an address generator 60. The address generator 60 (address generation circuit) generates access addresses (write address or read address) for accessing the memories 20 and 22. In more detail, the address generator 60 generates access addresses for writing the basic data portion into the basic data storage region and writing the extension data portion into the extension data storage region. The address generator 60 generates access addresses for reading the basic data portion from the basic data storage region and reading the extension data portion from the extension data storage region.

The memory controller 30 includes a memory I/F 70 and a memory I/F 72. The memory I/F 70 performs interface processing between the memory controller 30 and the memory 20, and the memory I/F 72 performs interface processing between the memory controller 30 and the memory 22. The memory I/F 70 and the memory I/F 72 include a circuit which generates control signals for the memories 20 and 22, a circuit which absorbs the difference in access cycle among various types of memories such as an SRAM and a DRAM, and the like. The memory I/F may be provided in a number corresponding to the number of physically divided memories, the number of banks, or the like.

Operation

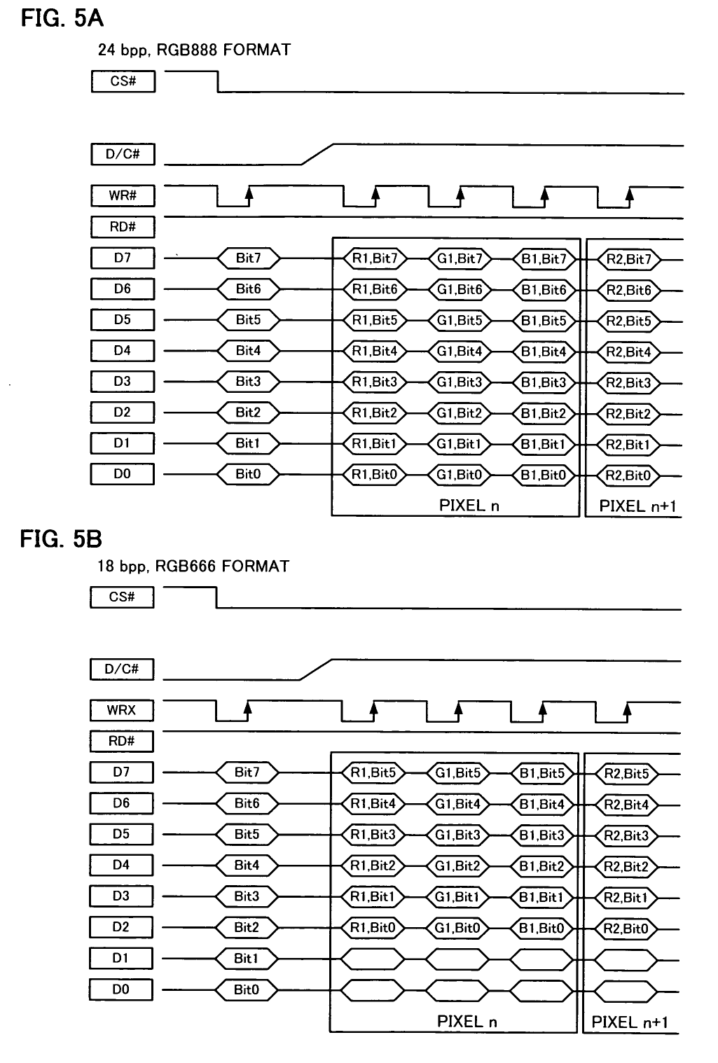

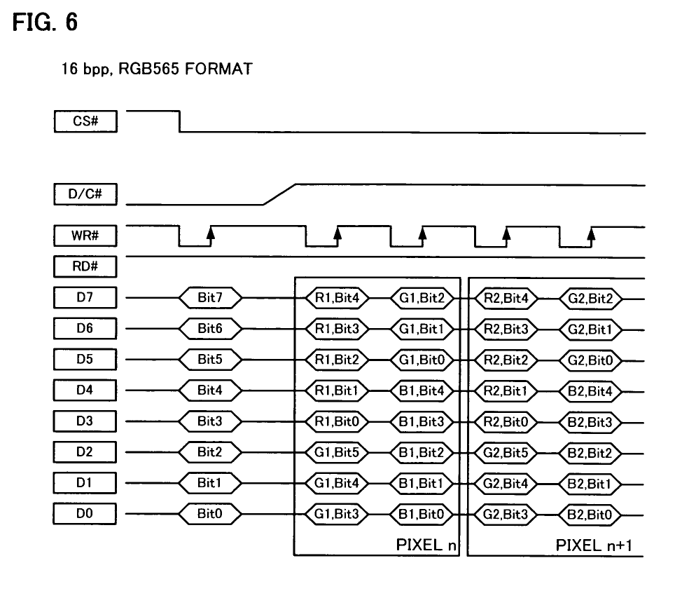

The operation according to one embodiment of the invention is described below. FIGS. 5A, 5B, and 6 show signal waveform examples of signal lines (bus) connecting the host I/F 12 and the host CPU 13. In FIGS. 5A to 6, CS#, D/C#, WR#, and RD# respectively indicate a chip select signal, an address/data select signal, a write signal, and a read signal. D7 to D0 indicate bus (address/data bus) signals. FIGS. 5A to 6 show examples in which the bus width (D0 to D7) is eight bits. However, the bus width may be 16 bits, 32 bits, 64 bits, or the like.

FIG. 5A is a signal waveform example when pixel data transferred from the host CPU 13 is in an RGB888 format (24 bpp). In FIG. 5A, R-component eight bits of a pixel “n” are transferred in a first write cycle, G-component eight bits are transferred in a second write cycle, and B-component eight bits are transferred in a third write cycle. Likewise, R-component eight bits of the next pixel “n+1” are transferred in a fourth write cycle, G-component eight bits are transferred in a fifth write cycle, and B-component eight bits are transferred in a sixth write cycle. This realizes transfer of pixel data in the RGB888 format in which each of the R, G, and B components is made up of eight bits.

FIG. 5B is a signal waveform example when pixel data transferred from the host CPU 13 is in an RGB666 format (18 bpp). In FIG. 5B, R-component six bits of the pixel “n” are transferred in the first write cycle, G-component six bits are transferred in the second write cycle, and B-component six bits are transferred in the third write cycle. The pixel data for the next pixel “n+1” is transferred in the same manner as described above.

FIG. 6 is a signal waveform example when pixel data transferred from the host CPU 13 is in an RGB565 format (16 bpp). In FIG. 6, R-component five bits and G-component three bits of the pixel “n” are transferred in the first write cycle, and G-component three bits and B-component five bits are transferred in the second write cycle. The pixel data for the next pixel “n+1” is transferred in the same manner as described above.

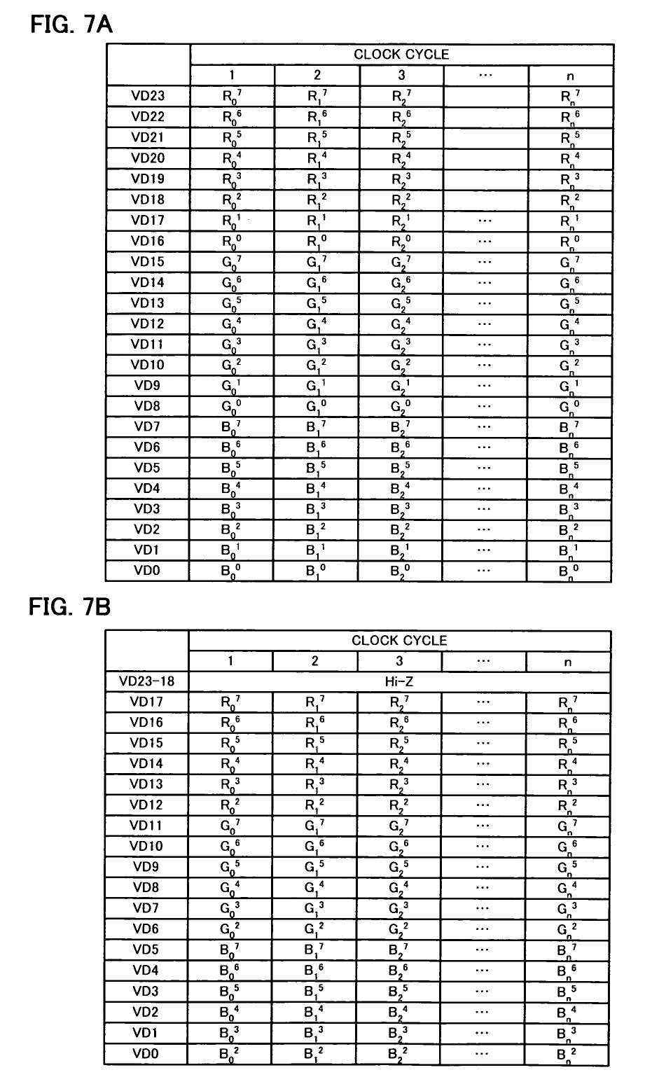

FIGS. 7A and 7B show format examples of data signals output from the display device I/F 14 to the display device 15.

FIG. 7A is an example when outputting pixel data in the RGB888 format to the display device 15. In FIG. 7A, 24-bit (24 bpp) pixel data made up of R, Q and B components, eight bits each, is output to the display device 15 in clock cycle units through data signal lines VD23 to VD0.

FIG. 7B is an example when outputting pixel data in the RGB666 format to the display device 15. In FIG. 7B, 18-bit (18 bpp) pixel data made up of R, Q and B components, six bits each, is output to the display device 15 in clock cycle units through the data signal lines VD17 to VD0. In this case, the data signal lines VD23 to VD18 are set in a high impedance state.

According to one embodiment of the invention, pixel data in various formats such as RGB888, RGB666, and RGB565 can be input as described above. However, 24-bit pixel data in the RGB888 format and 18-bit pixel data in the RGB666 format are data of which the number of bits is not a power of two.

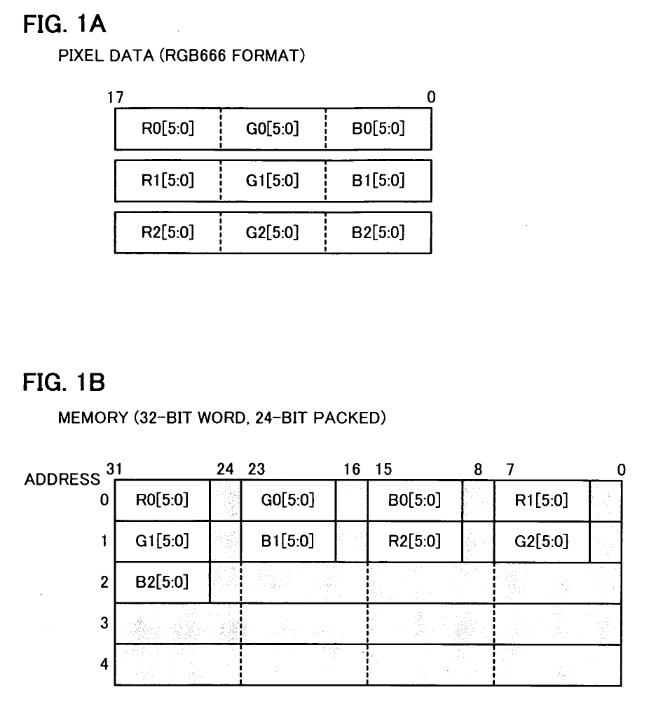

On the other hand, the host CPU 13 uses data or an address of which the number of bits is a power of two, such as 8 bits or 16 bits. When special memories are not used as the memories 20 and 22, the word length of the memories 20 and 22 is the number of bits which is a power of two. Therefore, a problem occurs in which the memory utilization efficiency is decreased, addressing of the host CPU 13 becomes complicated, or special memories having a word length of which the number of bits is not a power of two must be used as the memories 20 and 22, as described with reference to the related-art technologies shown in FIGS. 1A to 3B.

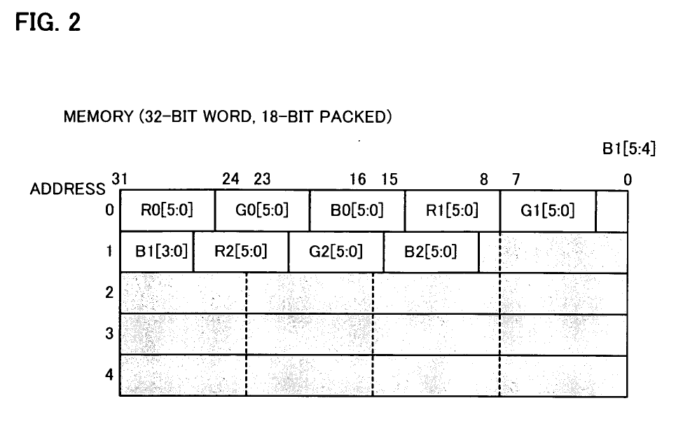

In a portable telephone or the like, the host CPU 13 must perform various types of processing in addition to the baseband engine processing. Therefore, if addressing becomes complicated as shown in FIG. 2 so that address calculation becomes complicated, the processing load of a program (firmware) operating on the host CPU 13 is significantly increased, whereby the performance of the entire system is decreased.

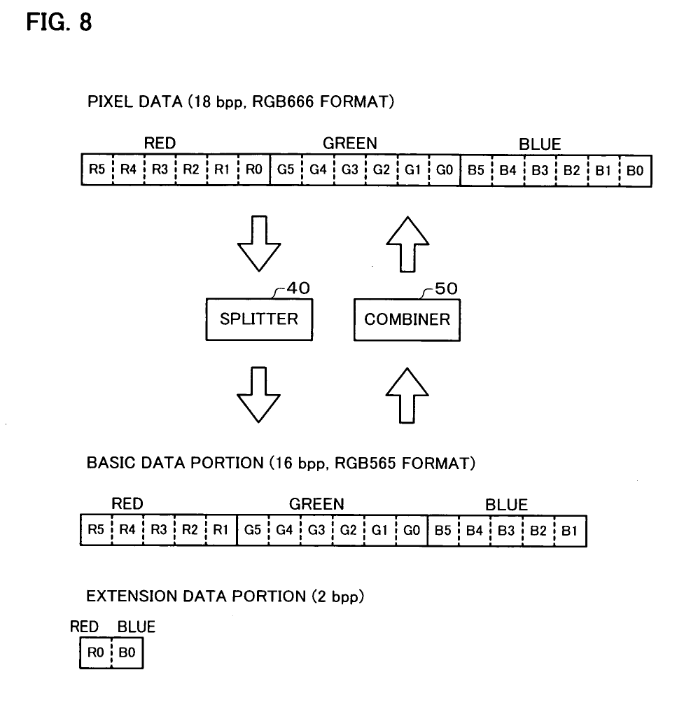

In order to solve such a problem, one embodiment of the invention uses the method shown in FIGS. 8 to 11.

In the RGB666 format input mode, the host CPU 13 writes pixel data in the RGB666 format by transmitting the pixel data to the host I/F 12 according to the signal waveform as shown in FIG. 5B. Then, the host I/F 12 issues an access request (write access request) to the memory controller 30 in order to write the received pixel data into the memories 20 and 22. The memory controller 30 (arbiter) then performs arbitration processing. When the access request from the host I/F 12 is accepted, the memory controller 30 starts processing of accessing the memories 20 and 22. In this case, the splitter 40 divides the pixel data into the basic data portion and the extension data portion, as shown in FIG. 8.

Specifically, the input pixel data is in the RGB666 format in which the R component is I1=6 bits, the G component is I2=6 bits, and the B component is I3=6 bits, as shown in FIG. 8. The splitter 40 divides the pixel data in the RGB666 format into the basic data portion in the RGB565 format, in which the R component is J1=5 bits, the G component is J2=6 bits, and the B component is J3=5 bits, and the extension data portion (2 bpp) in which the R component is K1=1 bit, the G component is K2=0 bit, and the B component is K3=1 bit. In more detail, the splitter 40 removes the least significant bit (R0) of the R component and the least significant bit (B0) of the B component from the pixel data in the RGB666 format (R5 to R0, G5 to G0, B5 to B0). The splitter 40 outputs the remaining data portion (R5 to R1, G5 to G0, and B5 to B1) as the basic data portion. The splitter 40 outputs the least significant bit (R0) of the R component and the least significant bit (B0) of the B component as the extension data portion.

The address generator 60 generates an access address (write address) for writing the basic data portion (R5 to R1, G5 to G0, and B5 to B1) into the basic data storage region. The memory I/F 70 writes the basic data portion into the basic data storage region of the memory 20 based on the access address. The address generator 60 generates an access address for writing the extension data portion (R0 and B0) into the extension data storage region. The memory I/F 72 writes the extension data portion into the extension data storage region of the memory 22 based on the access address.

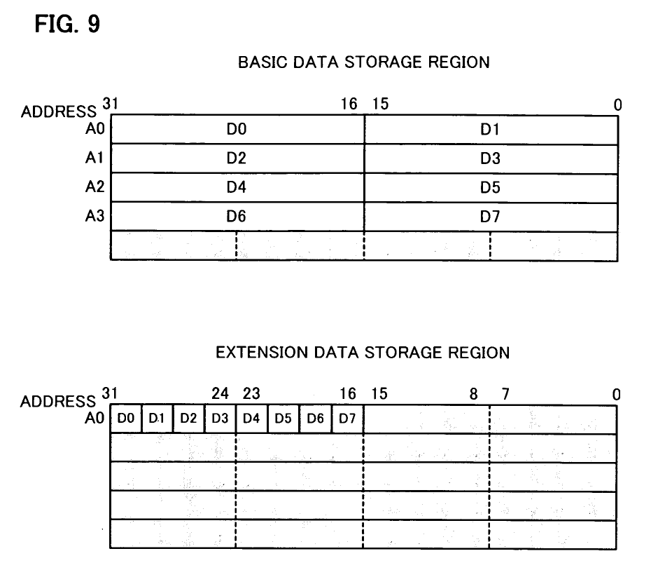

FIG. 9 shows a state in which the basic data portion and the extension data portion divided as shown in FIG. 8 are stored in the basic data storage region and the extension data storage region. In FIG. 9, the basic data storage region and the extension data storage region are allocated in memories having a word length of 32 (2^{P} in a broad sense) bits (power of two). The basic data portions of first and second pixel data D0 and D1 are stored at an address A0 in the basic data storage region, and the basic data portions of third and fourth pixel data D2 and D3 are stored at an address A1 in the basic data storage region. The basic data portions of pixel data D4 and D5 are stored at an address A2, and the basic data portions of pixel data D6 and D7 are stored at an address A3. The extension data portions of the first to eighth pixel data D0 to D7 are stored at an address A0 in the extension data storage region.

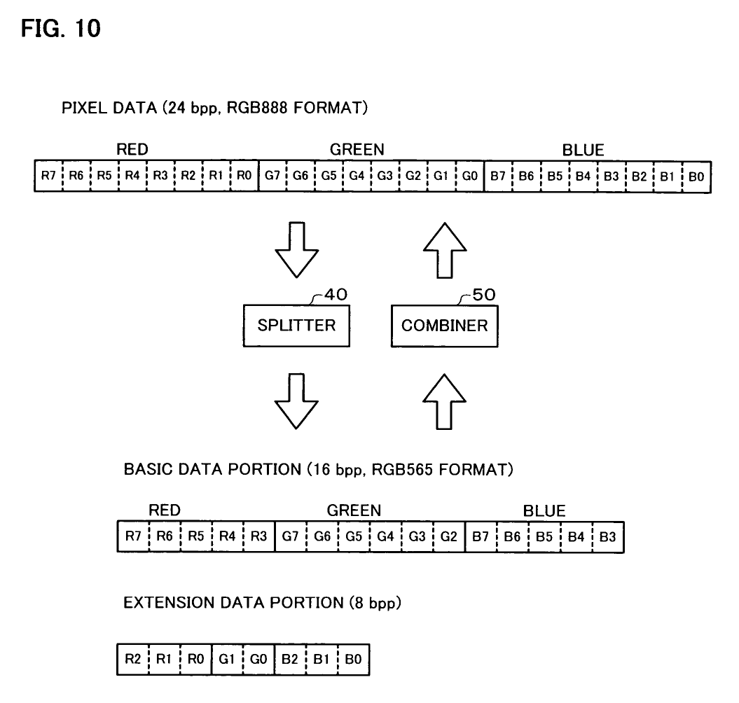

In the RGB888 format input mode, the host CPU 13 writes pixel data in the RGB888 format by transmitting the pixel data to the host I/F 12 according to the signal waveform as shown in FIG. 5A. The splitter 40 then divides the pixel data into the basic data portion and the extension data portion, as shown in FIG. 10.

Specifically, the input pixel data is in the RGB888 format in which the R component is I1=8 bits, the G component is I2=8 bits, and the B component is I3=8 bits, as shown in FIG. 10. The splitter 40 divides the pixel data in the RGB888 format into the basic data portion in the RGB565 format, in which the R component is J1=5 bits, the G component is J2=6 bits, and the B component is J3=5 bits, and the extension data portion in which the R component is K1=3 bits, the G component is K2=2 bits, and the B component is K3=3 bits. In more detail, the splitter 40 removes lower-order bits (R2, R1, R0) of the R component, lower-order bits (G1, G0) of the G component, and lower-order bits (B2, B1, B0) of the B component from the pixel data in the RGB888 format (R7 to R0, G7 to G0, B7 to B0). The splitter 40 outputs the remaining data portion (R7 to R3, G7 to G2, and B7 to B3) as the basic data portion. The splitter 40 outputs the lower-order bits (R2 to R0, G1 and G0, and B2 to B0) of the R, G, and B components as the extension data portion. The basic data portion and the extension data portion are respectively written into the basic data storage region and the extension data storage region based on the access addresses generated by the address generator 60.

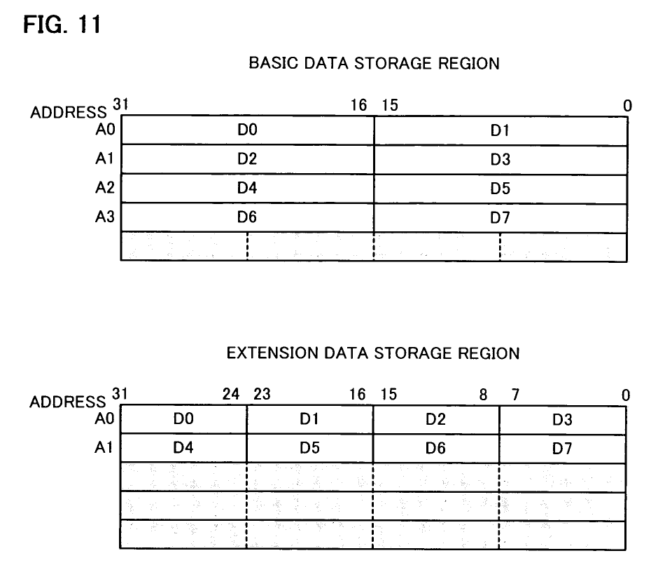

FIG. 11 shows a state in which the basic data portion and the extension data portion divided as shown in FIG. 10 are stored in the basic data storage region and the extension data storage region. In FIG. 11, the basic data storage region and the extension data storage region are allocated in memories having a word length of 32 bits (power of two). The basic data portions of the first and second pixel data D0 and D1 are stored at the address A0 in the basic data storage region. Likewise, the basic data portions of the pixel data D2 and D3 are stored at the address A1, the basic data portions of the pixel data D4 and D5 are stored at the address A2, and the basic data portions of the pixel data D6 and D7 are stored at the address A3. The extension data portions of the first to fourth pixel data D0 to D3 are stored at the address A0 in the extension data storage region, and the extension data portions of the fifth to eighth pixel data D4 to D7 are stored at the address A1 in the extension data storage region.

In the RGB565 format input mode, the host CPU 13 writes pixel data in the RGB565 format by transmitting the pixel data to the host I/F 12 according to the signal waveform as shown in FIG. 6.

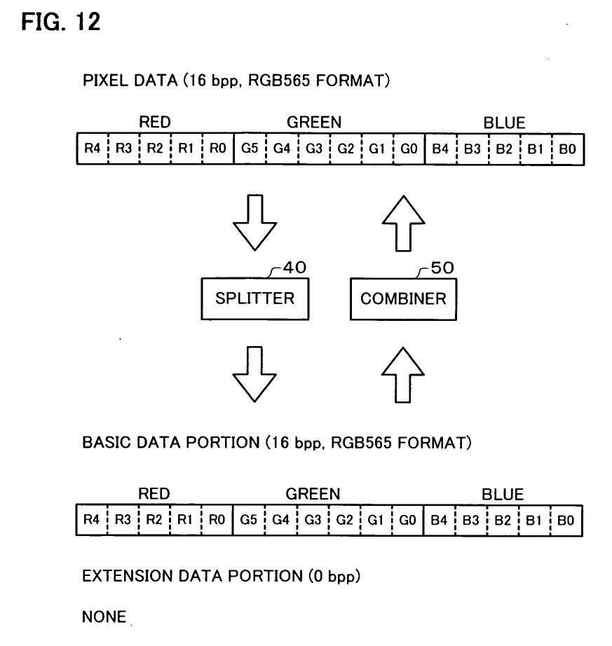

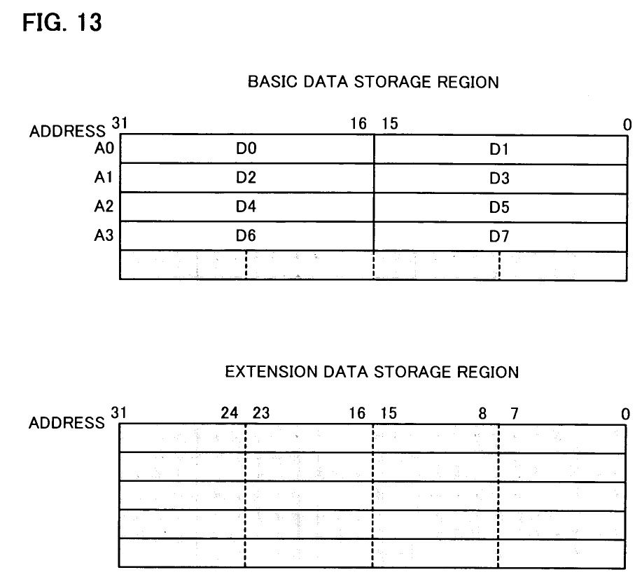

In this case, the input pixel data is in the RGB565 format in which the R component is I1=5 bits, the G component is I2=6 bits, and the B component is I3=5 bits, as shown in FIG. 12. The splitter 40 directly outputs the pixel data in the RGB565 format as the basic data portion, and the output basic data portion is written into the basic data storage region. Specifically, the extension data portion is not generated in the RGB565 format input mode, and only the basic data portion identical to the input pixel data is written into the basic data storage region, as shown in FIGS. 12 and 13.

According to one embodiment of the invention, since the pixel data is stored in the memory in a regular arrangement as shown in FIGS. 8 to 13, addressing is facilitated. Therefore, the configuration of the address generator 60 can be simplified. Specifically, according to one embodiment of the invention, the address generator 60 may generate the address A0 as the address of the basic data portions of the first and second pixel data D0 and D1, generate the address A1 as the address of the basic data portions of the third and fourth pixel data D2 and D3, and the like. Therefore, addressing can be simplified in comparison with the related-art technology shown in FIG. 2.

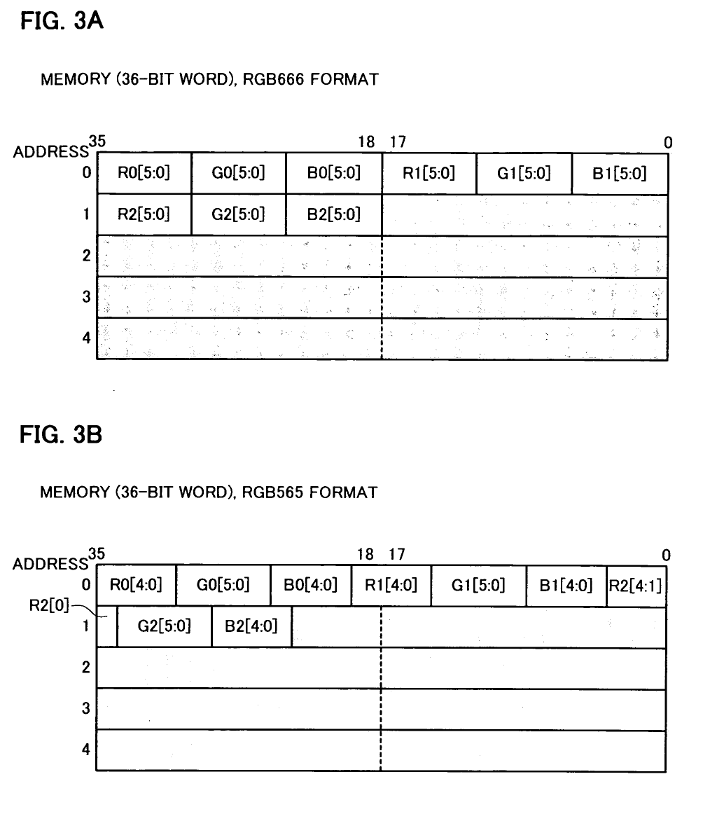

When dealing with the number of RGB formats (bit modes) by using a method of using a special memory having a word length of which the number of bits is not a power of two as in the related-art technology shown in FIG. 3A, while addressing can be simplified for one of the RGB formats, addressing cannot be simplified for the other RGB format.

According to one embodiment of the invention, as shown in FIGS. 8 to 13, when dealing with the number of RGB formats, addressing can be simplified for all the RGB formats. For example, simple addressing as shown in FIG. 9 can be realized even when the input pixel data is in the RGB666 format as shown in FIG. 8, and simple addressing as shown in FIG. 11 can be realized even when the input pixel data is in the RGB888 format as shown in FIG. 10. Moreover, when the input pixel data is in the RGB565 format, it suffices to write the basic data portion into the basic data storage region without generating the extension data portion, as shown in FIGS. 12 and 13, so that simple addressing can be realized.

According to one embodiment of the invention, pixel data can be stored while efficiently utilizing the memory, as shown in FIGS. 9, 11, and 13. Therefore, the memory utilization efficiency can be improved in comparison with the related-art technology shown in FIGS. 1A and 1B. Specifically, since it suffices to allocate only a minimum region in the memory, the memory storage capacity can be saved.

According to one embodiment of the invention, an ordinary memory having a word length of which the number of bits is a power of two can be used as the memory in which the basic data storage region or the extension data storage region is allocated. Therefore, the manufacturing process and the type of memory used are not limited, so that cost of the memory controller and the display controller can be reduced. In the related-art technology using a special memory as shown in FIGS. 3A and 3B, a commercially available external memory (memory having a word length of which the number of bits is a power of two) cannot be used as the memory in which the basic data storage region or the extension data storage region is allocated. However, one embodiment of the invention enable4s utilization of such an external memory.

According to one embodiment of the invention, when writing pixel data into the memories 20 and 22, the pixel data is automatically divided into the basic data portion and the extension data portion by the splitter 40, and the basic data portion and the extension data portion are respectively written into the basic data storage region and the extension data storage region. When reading pixel data from the memories 20 and 22, the basic data portion and the extension data portion stored in the basic data storage region and the extension data storage region are read and automatically combined by the combiner 50. Therefore, the host CPU 13 need not take into consideration that pixel data is divided into the basic data portion and the extension data portion and stored in the divided state. Therefore, the memory utilization efficiency can be increased without increasing the processing load imposed on the host CPU 13.

According to one embodiment of the invention, the basic data portion is in the general RGB565 format, as shown in FIGS. 8 to 13. Therefore, the number of bits can be converted (subtractive color processing) from the RGB666 format or the RGB888 format to the RGB565 format without correcting the memory data by merely removing the extension data portion from the pixel data in the RGB666 format or the RGB888 format (by merely omitting the extension data portion).

FIGS. 9, 11, and 13 show examples in which the memories 20 and 22 in which the basic data storage region and the extension data storage region are allocated have a word length of 32 bits. However, the invention is not limited thereto. The memories 20 and 22 may have a word length of 16 bits, 64 bits, 128 bits, 256 bits, or the like. When the memory 20 in which the basic data storage region is allocated is not physically identical with the memory 22 in which the extension data storage region is allocated, the word length of the memory 20 may differ from the word length of the memory 22. One embodiment of the invention illustrates the case where the basic data portion is in the RGB565 format as an example. However, the basic data portion according to the invention is not limited to the RGB565 format.

Detailed Configuration Example

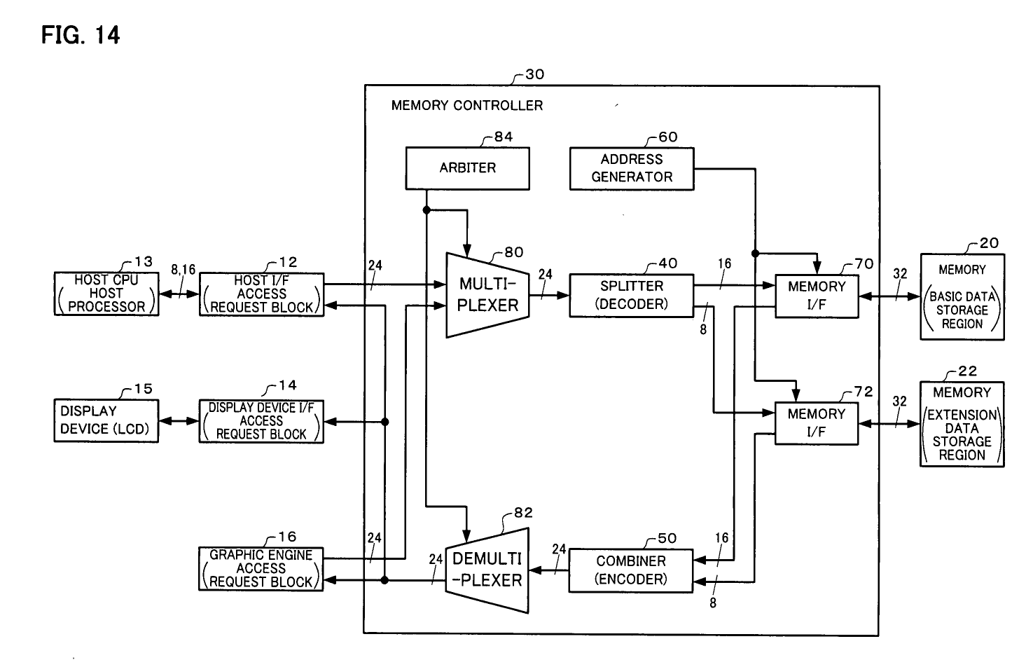

FIG. 14 shows a detailed configuration example of the memory controller and the display controller according to one embodiment of the invention. In FIG. 14, the memory controller 30 includes a multiplexer 80, a demultiplexer 82, and an arbiter 84 in addition to the splitter 40, the combiner 50, the address generator 60, the memory I/F 70, and the memory I/F 72.

The input of the multiplexer 80 is connected with the outputs of the host I/F 12 and the graphic engine 16 (access request blocks in a broad sense) through a 24-bit width ((I1+I2+I3)-bit width) bus, and the output of the multiplexer 80 is connected with the input of the splitter 40 through a 24-bit width bus. The output of the splitter 40 is connected with the input of the memory I/F 70 through a 16-bit width ((J1+J2+J3)-bit width) basic data portion transfer bus, and the output of the splitter 40 is connected with the input of the memory I/F 72 through an 8-bit width ((K1+K2+K3)-bit width) extension data portion transfer bus.

The output of the memory I/F 70 is connected with the input of the combiner 50 through a 16-bit width basic data portion transfer bus, and the output of the memory I/F 72 is connected with the input of the combiner 50 through a 8-bit width extension data portion transfer bus. The output of the combiner 50 is connected with the input of the demultiplexer 82 through a 24-bit width bus, and the output of the demultiplexer 82 is connected with the inputs of the host I/F 12, the display device I/F 14, and the graphic engine 16 through a 24-bit width bus.

In the RGB888 format input mode, signal lines of all the bits of the 24-bit width bus are used. In the RGB666 format input mode, signal lines of the lower-order 18 bits of the 24-bit width bus are used. In the RGB565 format input mode, the signal lines of the lower-order 16 bits are used.

The multiplexer 80 selects pixel data output from one of the host I/F 12 and the graphic engine 16 (access request blocks in a broad sense) requesting access to the memories 20 and 22. The multiplexer 80 outputs the selected pixel data to the splitter 40. In more detail, the arbiter 84 arbitrates between the access requests from the host I/F 12 and the graphic engine 16. When the arbiter 84 approves the access request from the host I/F 12, the multiplexer 80 outputs the pixel data from the host I/F 12 to the splitter 40. When the arbiter 84 approves the access request from the graphic engine 16, the multiplexer 80 outputs the pixel data from the graphic engine 16 to the splitter 40.

The splitter 40 divides the input pixel data into a basic data portion and an extension data portion, and outputs the basic data portion to the memory I/F 70 through the 16-bit width bus. The memory I/F 70 writes the basic data portion into the basic data storage region of the memory 20. The splitter 40 outputs the extension data portion to the memory I/F 72 through the 8-bit width bus. The memory I/F 72 writes the extension data portion into the extension data storage region of the memory 22.

The memory I/F 70 outputs the basic data portion read from the basic data storage region of the memory 20 to the combiner 50 through the 16-bit width bus. The memory I/F 72 outputs the extension data portion read from the extension data storage region of the memory 22 to the combiner 50 through the 8-bit width bus. The combiner 50 combines the basic data portion and the extension data portion, and outputs pixel data obtained by combination to the demultiplexer 82.

The demultiplexer 82 outputs the pixel data output from the combiner 50 to one of the host I/F 12, the display device I/F 14, and the graphic engine 16 (access request blocks in a broad sense) requesting access to the memories 20 and 22. In this case, the arbiter 84 arbitrates among the access requests.

The host CPU 13, the display device I/F 14 (display device 15), and the graphic engine 16 can access the memories 20 and 22 through the splitter 40 or the combiner 50 by providing the multiplexer 80 and the demultiplexer 82 as shown in FIG. 14. Therefore, not only addressing for the access request from the host CPU 13, but also addressing for the access request from the display device I/F 14 or the graphic engine 16 can be simplified. Specifically, the pixel data is automatically divided into the basic data portion and the extension data portion and written into the memories when the graphic engine 16 writes pixel data. The basic data portion and the extension data portion are read and automatically combined when the display device I/F 14 or the graphic engine 16 reads pixel data. This enables the circuit configurations of the display device I/F 14 and the graphic engine 16 to be simplified.

Subtractive color mode and complementary color mode

According to one embodiment of the invention, conversion of the number of bits in a subtractive color mode or a complementary color mode can be easily realized. In the subtractive color mode in which the number of bits of pixel data is reduced, the basic data portion stored in the basic data storage region is read and output as pixel data in the subtractive color mode.

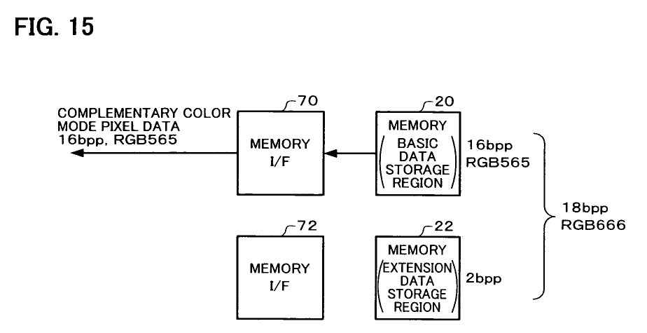

In FIG. 15, the basic data portion in the RGB565 format (16 bpp) is stored in the basic data storage region of the memory 20. The extension data portion (2 bpp) is stored in the extension data storage region of the memory 22. The basic data portion and the extension data portion have been respectively stored in the basic data storage region and the extension data storage region by dividing the pixel data in the RGB666 format (18 bpp) (original pixel data), as described with reference to FIGS. 8 and 9.

According to one embodiment of the invention, only the basic data portion in the RGB565 format stored in the basic data storage region is read in the subtractive color mode without reading the extension data portion (2 bpp) stored in the extension data storage region. The read basic data portion is output as the pixel data in the subtractive color mode. It is possible to deal with the case of displaying a screen consisting only of characters in the display device 15 in the subtractive color mode by outputting the pixel data in the subtractive color mode to the display device I/F 14, for example.

In the related-art technologies shown in FIGS. 1A to 3B, a circuit which deletes bits from pixel data is necessary in order to realize the subtractive color mode, so that the circuit scale is increased. According to one embodiment of the invention, since the subtractive color mode can be realized merely by reading the basic data portion from the basic data storage region, the circuit scale and power consumption can be reduced. A modification is also possible in which only a piece of extension data stored in the extension data storage region is read in the subtractive color mode.

According to one embodiment of the invention, the basic data portion stored in the basic data storage region is read in the complementary color mode in order to generate pixel data in the complementary color mode including the basic data portion and a complementary color data portion.

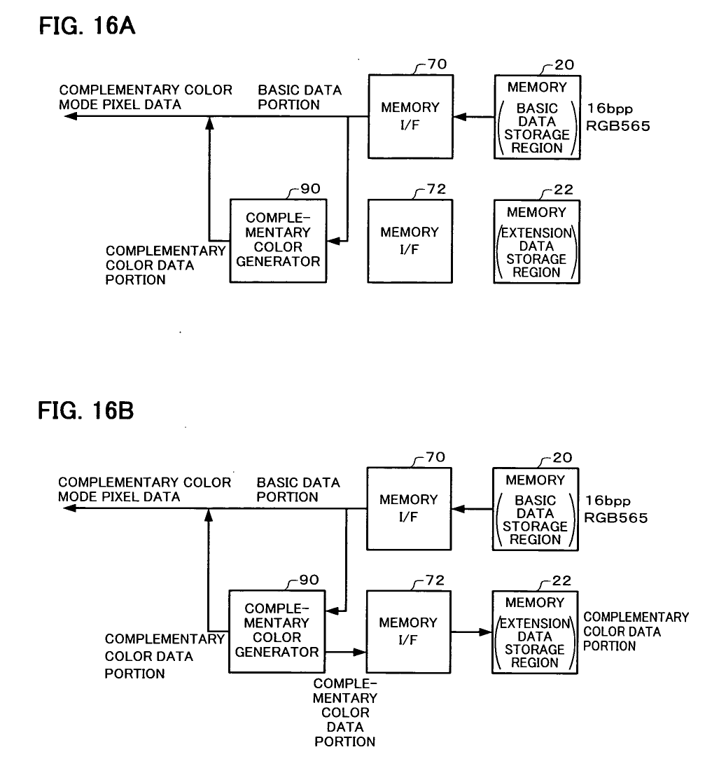

In FIG. 16A, the basic data portion in the RGB565 format (16 bpp) is stored in the basic data storage region of the memory 20. In the complementary color mode, the basic data portion in the RGB565 format is read from the basic data storage region. The memory controller 30 outputs pixel data including the basic data portion and the complementary color data portion as pixel data in the complementary color mode.

In this case, a complementary color generator 90 generates the complementary color data portion based on the basic data portion, as shown in FIG. 16A. The complementary color generator 90 may be realized by using a complementary color conversion table or the like. For example, the complementary color generator 90 generates a 2-bpp (S-bpp or S-bit in a broad sense) complementary color data portion corresponding to the data value of the basic data portion. The generated 2-bpp complementary color data portion is combined with the 16-bpp basic data portion, and the combined data is output as 18-bpp pixel data in the complementary color mode.

The complementary color data portion may be generated based on the basic data portion, or may be generated irrespective of the basic data portion. When generating the complementary color data portion irrespective of the basic data portion, the complementary color generator 90 may output fixed bit values as the complementary color data portion.

In the complementary color mode, the generated complementary color data portion may be written into the extension data storage region without rewriting the read basic data portion into the basic data storage region. In FIG. 16B, the complementary color data portion generated by the complementary color generator 90 is written into the extension data storage region of the memory 22. As a result, the pixel data in the complementary color mode is stored in the memories 20 and 22. When reading the pixel data in the complementary color mode from the memories 20 and 22, the basic data portion is read from the basic data storage region, and the complementary color data portion is read from the extension data storage region. The pixel data including (obtained by combining) the read basic data portion and complementary color data portion is output as the pixel data in the complementary color mode. This makes it possible to store the generated pixel data in the complementary color mode in the memories 20 and 22.

The invention is not limited to the above-described embodiments. Various modifications and variations may be made within the scope of the invention. For example, the terms (e.g. host CPU, R component, G component, and B component) cited in the description in the specification or the drawings as the terms in a broad sense or in a similar sense (e.g. host processor, first color component, second color component, and third color component) may be replaced by the terms in a broad sense or in a similar sense in another description in the specification or the drawings.

The configurations of the memory controller and the display controller according to the invention are not limited to the configurations described with reference to FIGS. 4, 14, and the like. Various modifications may be made as to the configurations of the memory controller and the display controller. For example, some of the constituent elements in the drawings may be omitted, or the connection relationship between the constituent elements may be changed. The division method and the combination method for the basic data portion and the extension data portion are not limited to the methods described with reference to FIGS. 8 to 13. For example, the division processing and the combination processing may be performed by changing the allocation of the number of bits and the bit configuration from those shown in FIGS. 8 to 13.

Although only some embodiments of the present invention have been described in detail above, those skilled in the art will readily appreciate that many modifications are possible in the embodiments without materially departing from the novel teachings and advantages of this invention. Accordingly, all such modifications are intended to be included within scope of this invention.

What is claimed is:

1. A memory controller which controls access to a memory which stores pixel data, the memory controller comprising:
a splitter which divides input pixel data, in which the number of bits of a first color component is I1 bits, the number of bits of a second color component is I2 bits, and the number of bits of a third color component is I3 bits, into a basic data portion and an extension data portion, the number of bits of the first color component being J1 bits, the number of bits of the second color component being J2 bits, and the number of bits of the third color component being J3 bits (J1+J2+J3=2^{M}) in the basic data portion, and the number of bits of the first color component being K1 bits, the number of bits of the second color component being K2 bits, and the number of bits of the third color component being K3 bits (K1+K2+K3=2^{N}) in the extension data portion; and
an address generator which generates access addresses for writing the basic data portion into a basic data storage region of the memory and writing the extension data portion into an extension data storage region of the memory.

2. The memory controller as defined in claim 1,
wherein the first color component, the second color component, and the third color component are respectively an R component, a G component, and a B component; and
wherein, when pixel data in an RGB666 format, in which I1=I2=I3=6, is input, the splitter divides the pixel data in the RGB666 format into a basic data portion in an RGB565 format, in which J1=5, J2=6, and J3=5, and an extension data portion in which K1=1, K2=0, and K3=1.

3. The memory controller as defined in claim 1,
wherein the first color component, the second color component, and the third color component are respectively an R component, a G component, and a B component; and
wherein, when pixel data in an RGB888 format, in which I1=I2=I3=8, is input, the splitter divides the pixel data in the RGB888 format into a basic data portion in an RGB565 format, in which J1=5, J2=6, and J3=5, and an extension data portion in which K1=3, K2=2, and K3=3.

4. The memory controller as defined in claim 2,
wherein, when pixel data in an RGB888 format, in which I1=I2=I3=8, is input, the splitter divides the pixel data in the RGB888 format into a basic data portion in an RGB565 format, in which J1=5, J2=6, and J3=5, and an extension data portion in which K1=3, K2=2, and K3=3.

5. The memory controller as defined in claim 2, wherein, when pixel data in an RGB565 format, in which I1=5, I2=6, and I3=5, is input, the input pixel data in the RGB565 format is written into the basic data storage region.

6. The memory controller as defined in claim 3, wherein, when pixel data in an RGB565 format, in which I1=5, I2=6, and I3=5, is input, the input pixel data in the RGB565 format is written into the basic data storage region.

7. The memory controller as defined in claim 4, wherein, when pixel data in an RGB565 format, in which I1=5, I2=6, and I3=5, is input, the input pixel data in the RGB565 format is written into the basic data storage region.

8. The memory controller as defined in claim 1, comprising:
a multiplexer which selects pixel data output from one of access request blocks requesting access to the memory, and outputs the selected pixel data to the splitter.

9. The memory controller as defined in claim 1, comprising:
a combiner which combines the basic data portion stored in the basic data storage region and the extension data portion stored in the extension data storage region, and outputs pixel data in which the number of bits of the first color component is I1 bits, the number of bits of the second color component is I2 bits, and the number of bits of the third color component is I3 bits.

10. The memory controller as defined in claim 9, comprising:
a demultiplexer which outputs the pixel data output from the combiner to one of access request blocks which request access to the memory.

11. The memory controller as defined in claim 1,
wherein, in a subtractive color mode, the basic data portion stored in the basic data storage region is read and output as pixel data in the subtractive color mode.

12. The memory controller as defined in claim 1,
wherein, in a complementary color mode, the basic data portion stored in the basic data storage region is read in order to generate pixel data in the complementary color mode including the basic data portion and a complementary color data portion.

13. The memory controller as defined in claim 12,
wherein the complementary color data portion is generated based on the read basic data portion.

14. The memory controller as defined in claim 12,
wherein, in the complementary color mode, the generated complementary color data portion is written into the extension data storage region.

15. A display controller, comprising:
the memory controller as defined in claim 1; and
a display device interface which performs interface processing between the display controller and a display device.

16. A display controller, comprising:
the memory controller as defined in claim 9; and
a display device interface which performs interface processing between the display controller and a display device.

17. The display controller as defined in claim 15, comprising:
a host interface connected with a host processor through a 2^{R}-bit bus and performing interface processing between the display controller and the host processor.

18. A display controller, comprising:
the memory controller as defined in claim 1; and
at least one memory in which the basic data storage region and the extension data storage region are allocated.

19. A display controller, comprising:
the memory controller as defined in claim 9; and
at least one memory in which the basic data storage region and the extension data storage region are allocated.

20. A method of controlling a memory which stores pixel data, the method comprising:
dividing input pixel data, in which the number of bits of a first color component is I1 bits, the number of bits of a second color component is I2 bits, and the number of bits of a third color component is I3 bits, into a basic data portion and an extension data portion, the number of bits of the first color component being J1 bits, the number of bits of the second color component being J2 bits, and the number of bits of the third color component being J3 bits (J1+J2+J3=2^{M}) in the basic data portion, and the number of bits of the first color component being K1 bits, the number of bits of the second color component being K2 bits, and the number of bits of the third color component being K3 bits (K1+K2+K3=2^{N}) in the extension data portion; and
writing the basic data portion into a basic data storage region of the memory and writing the extension data portion into an extension data storage region of the memory.
